(19) United States
(12) Patent Application Publication
(10) Pub. No.: US 2025/0204157 A1
(43) Pub. Date: Jun. 19, 2025

(54) DISPLAY PANEL, METHOD FOR PREPARING SAME, AND DISPLAY DEVICE

(71) Applicants: Beijing BOE Technology Development Co., Ltd., Beijing (CN); BOE Technology Group Co., Ltd., Beijing (CN)

(72) Inventors: Renrong GAI, Beijing (CN); Shantao CHEN, Beijing (CN); Jing WANG, Beijing (CN); Yonghui LIU, Beijing (CN); Zibo NI, Beijing (CN)

(21) Appl. No.: 18/579,496

(22) PCT Filed: Apr. 23, 2023
(86) PCT No.: PCT/CN2023/090133

§ 371 Date: Jan. 15, 2024

(51) Int. Cl. H10K 59/122; H10K 59/12; H10K 59/124; H10K 59/35; H10K 59/80

(52) U.S. Cl. CPC H10K 59/122; H10K 59/1201; H10K 59/124; H10K 59/8792; H10K 59/353

(57) ABSTRACT

Provide is a display panel. The display panel includes a driver backplane, a pixel definition layer, and a plurality of light-emitting devices. The pixel definition layer is disposed on a side of the driver backplane, and a plurality of openings are formed in the pixel definition layer. Each of the light-emitting devices includes a normal element and at least one privacy element. The privacy element and the normal element are disposed in different openings. A slope angle of a portion of the pixel definition layer, wherein at least a partial edge of the opening where the privacy element is disposed is disposed on the portion, is greater than a slope angle of a portion of the pixel definition layer, wherein an edge of the opening where the normal element is disposed is disposed on the portion.

### CROSS-REFERENCE TO RELATED APPLICATION

The present disclosure is a U.S. national stage of international application No. PCT/CN2023/090133, filed on Apr. 23, 2023, the content of which is herein incorporated by reference in its entirety.

### TECHNICAL FIELD

The present disclosure relates to the field of display technologies, and in particular, relates to a display panel, a method for preparing the same, and a display device.

### BACKGROUND

Organic light-emitting diode (OLED) displays have arouse widespread concern for their advantages of self-luminescence, low power consumption, thinness, flexibility, vivid colors, high contrast, and fast response rate.

### SUMMARY

According to some embodiments of the present disclosure, a display panel is provided. The display panel includes a driver backplane, a pixel definition layer, and a plurality of light-emitting devices; wherein
the pixel definition layer is disposed on a side of the driver backplane, and a plurality of openings are formed in the pixel definition layer;
each of the light-emitting devices includes a normal element and at least one privacy element, wherein the privacy element and the normal element are respectively disposed in different openings of the plurality of openings; and
a slope angle of a portion of the pixel definition layer, wherein at least a partial edge of the opening where the privacy element is disposed is disposed on the portion, is greater than a slope angle of a portion of the pixel definition layer, wherein an edge of the opening where the normal element is disposed is disposed on the portion.

In some embodiments, the slope angle of the portion of the pixel definition layer, wherein the edge of the opening where the privacy element is disposed is disposed on the portion, ranges from 60° to 90°; and
the slope angle of the portion of the pixel definition layer, wherein the edge of the opening where the normal element is disposed is disposed on the portion, ranges from 20° to 30°.

In some embodiments, the pixel definition layer is made of a black light-absorbing material.

In some embodiments, a surface on a side, away from the driver backplane, of the pixel definition layer disposed between the normal element and the privacy element that are adjacent to each other is a curved surface;
points, farthest from the driver backplane, on the curved surfaces are connected to form a line, wherein a distance between an orthographic projection of the line on the driver backplane and an orthographic projection on the driver backplane of a first edge of the opening where the privacy element is disposed is less than a distance between the orthographic projection of the line on the driver backplane and an orthographic projection on the driver backplane of a second edge of the opening where the normal element is disposed; and
the orthographic projections of the first edge and the second edge on the driver backplane are disposed between orthographic projections of the normal element and the privacy element on the driver backplane, and the orthographic projections of the first edge and the second edge on the driver backplane are adjacent to each other.

In some embodiments, equations for calculating a distance A between the point, farthest from the driver backplane, on the curved surface and the driver backplane are as follows:

$$tan θ = A / D ;$$

$$tan θ1 = A / ( D - B ) ;$$

$$tan θ2 = A / [ C - ( D - B ) ] ; and$$

$$A = tan θ * D = tan θ1 * ( D - B ) = tan θ2 * [ C - ( D - B ) ] ;$$

wherein
B represents an opening width, along an arrangement direction of the privacy element and the normal element, of the opening where the privacy element is disposed;
C represents a maximum width, along the arrangement direction of the privacy element and the normal element, of the pixel definition layer disposed between the privacy element and the normal element that are adjacent to each other;
D represents a sum, along the arrangement direction of the privacy element and the normal element, of B and a distance between an orthographic projection on the driver backplane of the point, farthest from the driver backplane, on the curved surface and the orthographic projection of the first edge on the driver backplane; and
θ=90°−α/2, wherein α represents a viewing angle of the privacy element;
θ1 represents the slope angle of the portion of the pixel definition layer, wherein the edge of the opening where the privacy element is disposed is disposed on the portion; and
θ2 represents the slope angle of the portion of the pixel definition layer, wherein the edge of the opening where the normal element is disposed is disposed on the portion.

In some embodiments, a surface on a side, away from the driver backplane, of the pixel definition layer disposed between adjacent two of the privacy elements is a curved surface,
wherein the adjacent two privacy elements are respectively a first privacy element and a second privacy element;
points, farthest from the driver backplane, on the curved surfaces are connected to form a line, wherein a distance between an orthographic projection of the line on the driver backplane and an orthographic projection on the driver backplane of a first edge of an opening where the first privacy element is disposed is equal to a distance between the orthographic projection of the line on the driver backplane and an orthographic projection on the driver backplane of a second edge of an opening where the second privacy element is disposed; and
the orthographic projections of the first edge and the second edge on the driver backplane are disposed between orthographic projections of the first privacy element and the second privacy element on the driver backplane, and the orthographic projections of the first edge and the second edge on the driver backplane are adjacent to each other.

In some embodiments, equations for calculating a distance A1 between the point, farthest from the driver backplane, on the curved surface and the driver backplane are as follows:

$$tan θ3 = A 1 / D 1 ;$$

$$tan θ4 = A 1 / D 1 ;$$

$$tan θ5 = A 1 / [ C 1 - ( D 1 - B 1 ) ] ; and$$

$$A 1 = tan θ3 * D 1 = tan θ4 * ( D 1 - B 1 ) = tan θ5 * [ C 1 - ( D 1 - B 1 ) ] ;$$

wherein
B1 represents an opening width, along an arrangement direction of the first privacy element and the second privacy element, of the opening where the first privacy element is disposed;
C1 represents a maximum width, along the arrangement direction of the first privacy element and the second privacy element, of the pixel definition layer disposed between the first privacy element and the second privacy element;
D1 represents a sum, along the arrangement direction of the first privacy element and the second privacy element, of B1 and a distance between an orthographic projection on the driver backplane of the point, farthest from the driver backplane, on the curved surface and the orthographic projection of the first edge on the driver backplane; and
θ3=90°−α/2, wherein α represents a viewing angle of the first privacy element;
θ4 represents a slope angle of a portion of the pixel definition layer, wherein an edge of the opening where the first privacy element is disposed is disposed on the portion; and
θ5 represents a slope angle of a portion of the pixel definition layer, wherein an edge of the opening where the second privacy element is disposed is disposed on the portion.

In some embodiments, a surface on a side, away from the driver backplane, of the pixel definition layer disposed between adjacent two of the normal elements is a curved surface,
wherein the adjacent two normal elements are respectively a first normal element and a second normal element;
points, farthest from the driver backplane, on the curved surfaces are connected to form a line, wherein a distance between an orthographic projection of the line on the driver backplane and an orthographic projection on the driver backplane of a first edge of an opening where the first normal element is disposed is equal to a distance between the orthographic projection of the line on the driver backplane and an orthographic projection on the driver backplane of a second edge of an opening where the second normal element is disposed; and
the orthographic projections of the first edge and the second edge on the driver backplane are disposed between orthographic projections of the first normal element and the second normal element on the driver backplane, and the orthographic projections of the first edge and the second edge on the driver backplane are adjacent to each other.

In some embodiments, equations for calculating a distance A2 between the point, farthest from the driver backplane, on the curved surface and the driver backplane are as follows:

$$tan θ6 = A 2 / D 2 ;$$

$$tan θ7 = A 2 / ( D 2 - B 2 ) ;$$

$$tan θ8 = A 2 / [ C 2 - ( D 2 - B 2 ) ] ; and$$

$$A 2 = tan θ6 * D 2 = tan θ7 * ( D 2 - B 2 ) = tan θ8 * [ C 2 - ( D 2 - B 2 ) ] ;$$

wherein
B2 represents an opening width, along an arrangement direction of the first normal element and the second normal element, of the opening where the first normal element is disposed;
C2 represents a maximum width, along the arrangement direction of the first normal element and the second normal element, of the pixel definition layer disposed between the first normal element and the second normal element;
D2 represents a sum, along the arrangement direction of the first normal element and the second normal element, of B2 and a distance between an orthographic projection on the driver backplane of the point, farthest from the driver backplane, on the curved surface and the orthographic projection of the first edge on the driver backplane; and
θ6=90°−α1/2, wherein α1 represents a viewing angle of the first normal element;
θ7 represents a slope angle of a portion of the pixel definition layer, wherein an edge of the opening where the first normal element is disposed is disposed on the portion; and
θ8 represents a slope angle of a portion of the pixel definition layer, wherein an edge of the opening where the second normal element is disposed is disposed on the portion.

In some embodiments, α ranges from 40° to 50°.

In some embodiments, α1 ranges from 120° to 160°.

In some embodiments, the plurality of light-emitting devices include a plurality of red light-emitting devices, a plurality of green light-emitting devices, and a plurality of blue light-emitting devices; wherein
the red light-emitting devices include a red privacy element and a red normal element;
the green light-emitting devices include a green privacy element and a green normal element;
the blue light-emitting devices include a blue privacy element and a blue normal element;
portions of the pixel definition layer have a same slope angle, wherein edges of openings, where the red privacy element, the green privacy element and the blue privacy element are respectively disposed, are respectively disposed on the portions; and
portions of the pixel definition layer have a same slope angle, wherein edges of openings, where the red privacy element, the green privacy element and the blue privacy element are respectively disposed, are respectively disposed on the portions.

In some embodiments, the display panel further includes: a first light-shielding structure disposed on the side, away from the driver backplane, of the pixel definition layer;
wherein an orthographic projection of the first light-shielding structure on the driver backplane is disposed at an edge of an orthographic projection on the driver backplane of an opening where the privacy element is disposed, and the orthographic projection of the first light-shielding structure on the driver backplane at least covers the orthographic projection on the driver backplane of the line formed by connecting the points, farthest from the driver backplane, on the curved surfaces.

In some embodiments, the display panel further includes: a package layer and a second light-shielding structure; wherein
the package layer is disposed on a side, away from the driver backplane, of the first light-shielding structure and is configured to package the light-emitting device;
the package layer includes more than three sub-layers, wherein the more than three sub-layers are successively stacked along a direction away from the driver backplane;
the second light-shielding structure is disposed between at least some of the adjacent sub-layers; and
an orthographic projection of the second light-shielding structure on the driver backplane is disposed at the edge of the orthographic projection on the driver backplane of the opening where the privacy element is disposed, and the orthographic projection of the second light-shielding structure on the driver backplane is at least partially overlapped with the orthographic projection of the first light-shielding structure on the driver backplane.

In some embodiments, equations for calculating a width W, along an arrangement direction of the privacy element and the normal element, of the first light-shielding structure and a height H, along a direction away from the driver backplane, of the first light-shielding structure are as follows:

$$tan θ = ( A + H ) / D ;$$

$$tan θ2 = ( A + H ) / ( C - W - x ) ; and$$

$$tan θ1 = A / x ;$$

wherein
A represents a distance between the point, farthest from the driver backplane, on the curved surface and the driver backplane;
D represents a sum, along the arrangement direction of the privacy element and the normal element, of B and a distance between an orthographic projection on the driver backplane of the point, farthest from the driver backplane, on the curved surface and the orthographic projection of the first edge on the driver backplane;
B represents an opening width, along the arrangement direction of the privacy element and the normal element, of the opening where the privacy element is disposed;
C represents a maximum width, along the arrangement direction of the privacy element and the normal element, of the pixel definition layer disposed between the privacy element and the normal element that are adjacent to each other;
x represents a shortest distance between the orthographic projection of the first light-shielding structure on the driver backplane and the orthographic projection of the first edge on the driver backplane; and
θ=90°−α/2, wherein α represents a viewing angle of the privacy element;
θ1 represents a slope angle of a portion of the pixel definition layer, wherein an edge of the opening where the privacy element is disposed is disposed on the portion; and
θ2 represents a slope angle of a portion of the pixel definition layer, wherein an edge of the opening where the normal element is disposed is disposed on the portion.

In some embodiments, the first light-shielding structure and the second light-shielding structure are made of a black organic material.

According to some embodiments of the present disclosure, a method for preparing a display panel is provided. The method includes:
preparing a driver backplane;
preparing anodes of a plurality of light-emitting devices on a side of the driver backplane, wherein preparing the anodes of the plurality of light-emitting devices includes preparing anodes of normal elements and anodes of privacy elements by a one-time patterning process; and
preparing a pixel definition layer and a plurality of openings in the pixel definition layer on a side, away from the driver backplane, of the anode;
wherein a slope angle of a portion of the pixel definition layer, wherein at least a partial edge of an opening where the privacy element is disposed is disposed on the portion, is greater than a slope angle of a portion of the pixel definition layer, wherein an edge of an opening where the normal element is disposed is disposed on the portion.

In still another aspect, some embodiments of the present disclosure further provide a display device. The display device includes the display panel as described above.

### BRIEF DESCRIPTION OF DRAWINGS

For clearer descriptions of the technical solutions in the embodiments of the present disclosure, the following briefly introduces the accompanying drawings to be required in the descriptions of the embodiments. Apparently, the accompanying drawings in the following description show merely some embodiments of the present disclosure, and persons of ordinary skills in the art may still derive other drawings from these accompanying drawings without creative efforts.

FIG. 1 shows a schematic diagram of a sharing state and a privacy state when a display product is displayed in some practices.

FIG. 2a is a top-view schematic structural diagram of a display panel according to some embodiments of the present disclosure.

FIG. 2b is a sectional schematic diagram of a structure along a section line AA in FIG. 2a.

FIG. 2c is a sectional schematic diagram of a structure along a section line BB in FIG. 2a.

FIG. 2d is a sectional schematic diagram of a structure along a section line CC in FIG. 2a.

FIG. 2e is a schematic diagram of a range of light emitting angles of a normal element and a privacy element according to some embodiments of the present disclosure.

FIG. 2f is a sectional schematic diagram of a structure along the section line AA in FIG. 2a.

FIG. 2g is another sectional schematic diagram of a structure along the section line AA in FIG. 2a.

FIG. 2h is still another sectional schematic diagram of a structure along the section line AA in FIG. 2a.

FIG. 2i is yet still another sectional schematic diagram of a structure along the section line AA in FIG. 2a.

FIG. 2j is a top-view schematic diagram of an arrangement of a first light-shielding structure and a second light-shielding structure according to some embodiments of the present disclosure.

FIG. 3a is a schematic diagram of step S032 in a method for preparing a display panel according to some embodiments of the present disclosure.

FIG. 3b is a schematic diagram of step S033 in a method for preparing a display panel according to some embodiments of the present disclosure.

FIG. 3c is a comparative diagram of parameters and effects of slope angles of pixel definition layers formed by a hot-in-cold-out hot box in a method for preparing a display panel according to some embodiments of the present disclosure.

FIG. 3d is a schematic diagram of another method for preparing a display panel according to some embodiments of the present disclosure.

### DETAILED DESCRIPTION

The present disclosure is described in further detail with reference to the accompanying drawings, to clearly present the objects, technical solutions, and advantages of the present disclosure.

The embodiments of the present disclosure will be described more fully hereinafter with reference to the accompanying drawings, but the embodiments may be embodied in different forms and should not be construed as being limited to the embodiments illustrated in the present disclosure. Instead, these embodiments are provided for the purpose of making the present disclosure thorough and complete, and those skilled in the art may fully understand the scope of the present disclosure.

The embodiments of the present disclosure are not limited to the embodiments illustrated in the accompanying drawings but include modifications to configurations based on manufacturing processes. Accordingly, the regions exemplified in the accompanying drawings have schematic properties, and the shapes of the regions shown in the drawings exemplify specific shapes of the regions, but are not intended to be limiting.

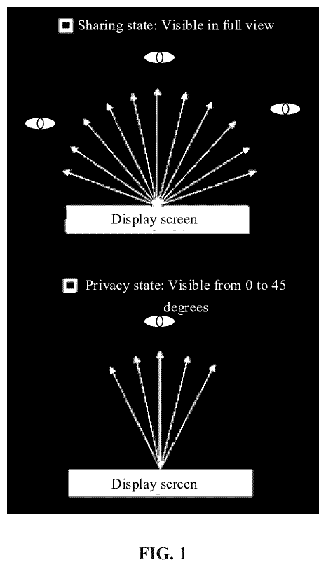

In some practices, referring to FIG. 1, which is a schematic diagram of a sharing state and a privacy state of a display product in some practices when the display product is displayed, with more and more applications of the display, people would like to share information with others, but would like to have the privacy in special cases. For example, when dealing with confidential information, the information is easy to be seen by other people next to us; and also, for example, when entering personal information on a cell phone, the personal information is easy to be seen by other people. Therefore, it is gradually becoming a trend for display products to switch between a sharing state and a privacy state when displaying images or data.

Based on the demand for display products to switch between the sharing state and the privacy state when displaying images or data, in some practices, an external privacy film is deployed on a display screen, which is manually hung in front of the display screen when it is needed to be private, and then manually removed when it is not needed; and there is also a liquid crystal layer arranged on a display side of the display screen in some practices, which restricts the light emitting angle the display screen by the liquid crystal reorientation in the liquid crystal layer.

It is cumbersome to manually hang the privacy film, such that the switching between the sharing state and the privacy state is not flexible and convenient. Arranging the liquid crystal layer on the display side of the display screen increases a thickness of the display screen, which does not satisfy the user's needs well.

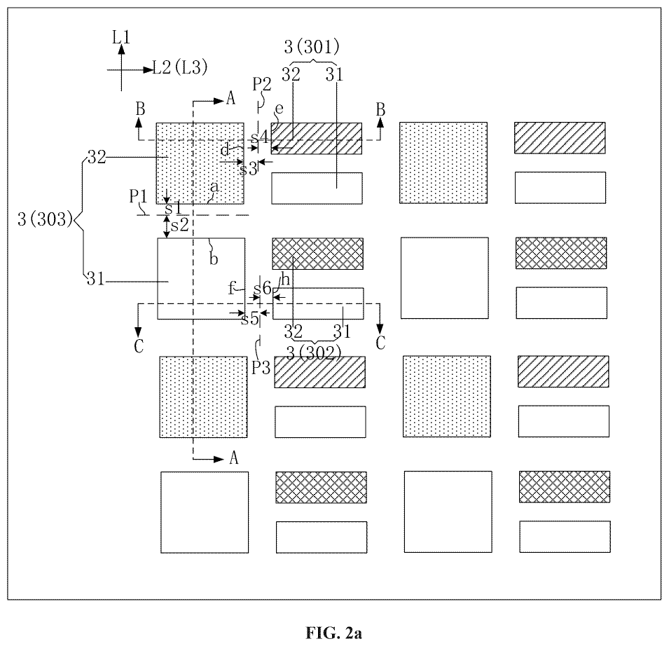

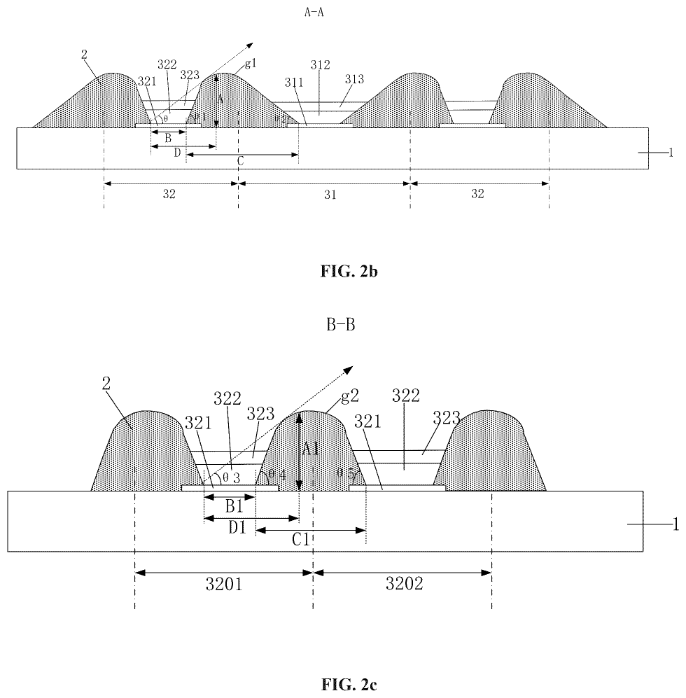

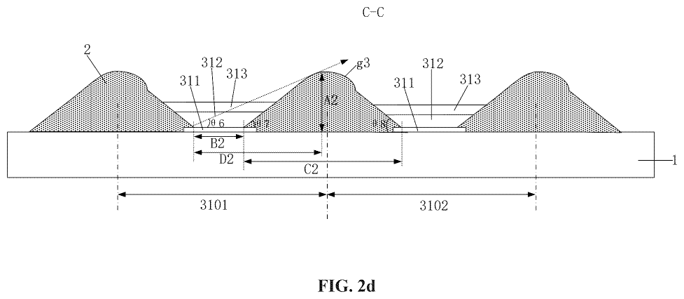

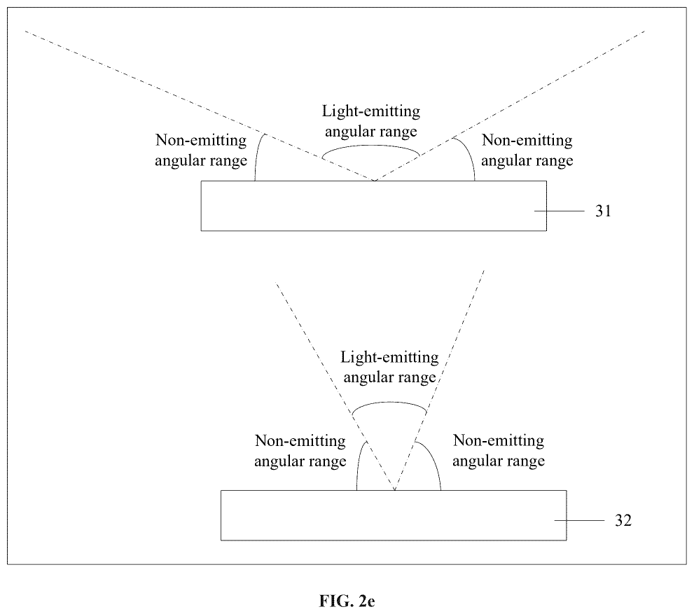

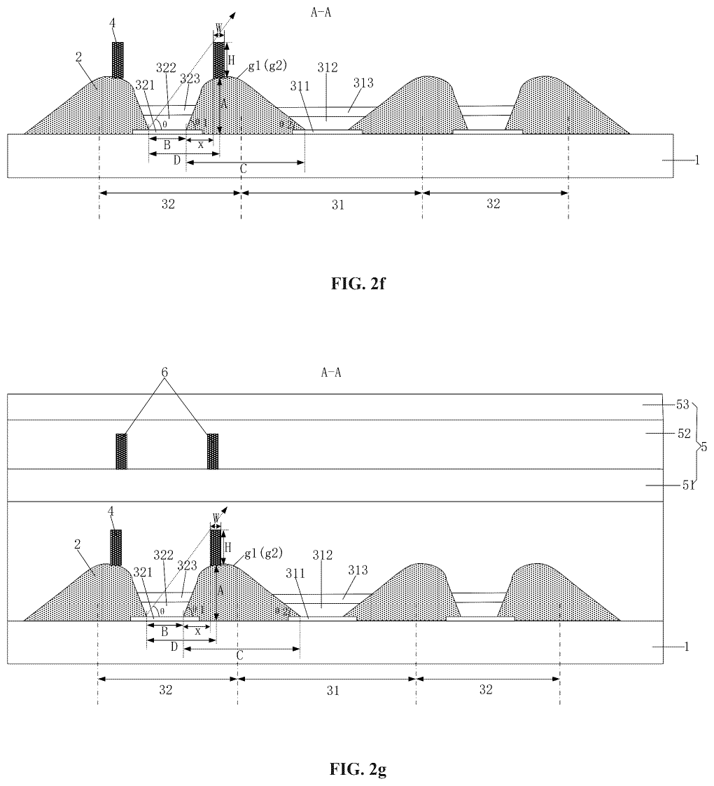

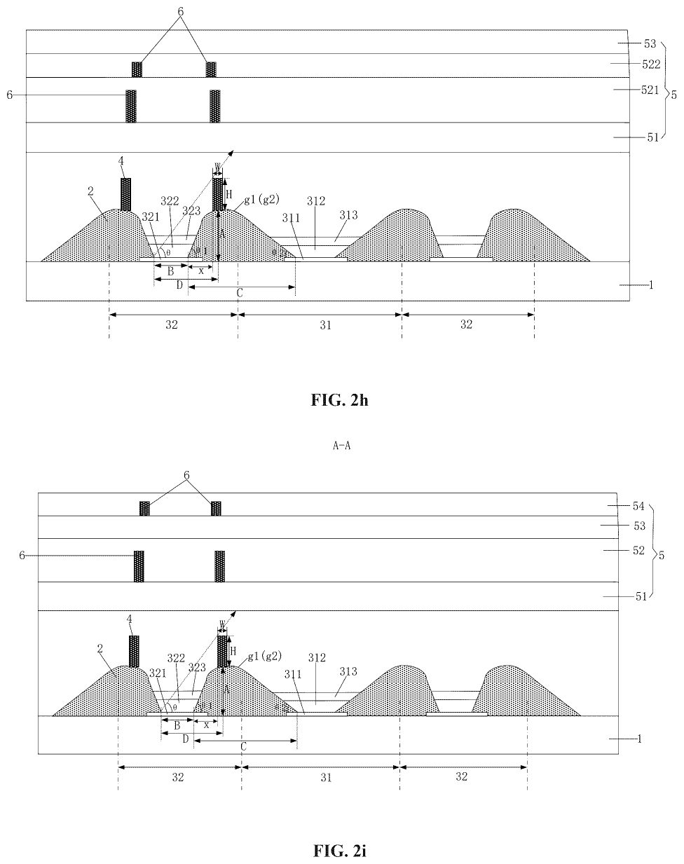

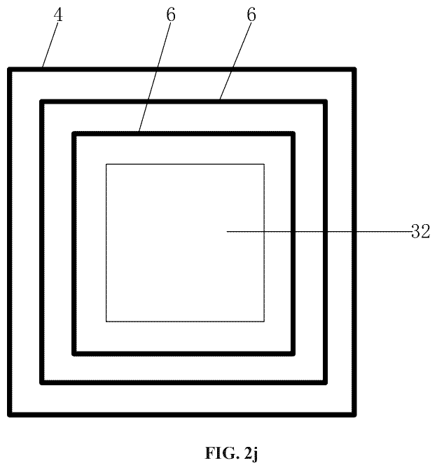

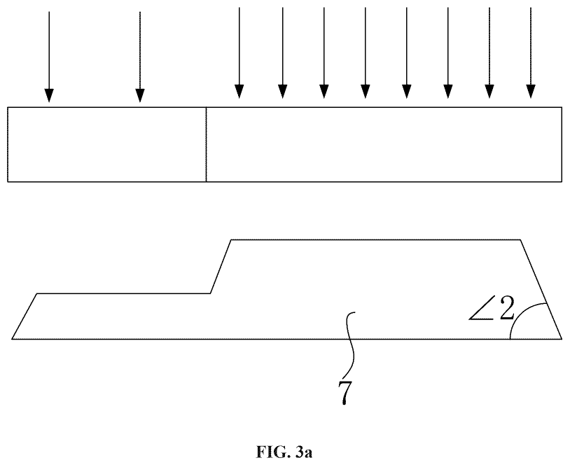

To address the problem in some practices that the switching between the sharing state and the privacy state of the display product is not convenient and quick, the embodiments of the present disclosure provide a display panel. FIG. 2a is a top-view schematic structural diagram of a display panel according to some embodiments of the present disclosure. FIG. 2b is a sectional schematic diagram of a structure along a section line AA in FIG. 2a. FIG. 2c is a sectional schematic diagram of a structure along a section line BB in FIG. 2a. FIG. 2d is a sectional schematic diagram of a structure along a section line CC in FIG. 2a. Referring to FIG. 2a, FIG. 2b, FIG. 2c, and FIG. 2d, the display panel includes a driver backplane 1, a pixel definition layer 2, and a plurality of light-emitting devices 3. The pixel definition layer 2 is disposed on a side of the driver backplane 1, and a plurality of openings are defined in the pixel definition layer 2. The light-emitting device 3 includes a normal element 31 and at least one privacy element 32. The privacy element 32 and the normal element 31 are respectively disposed in different openings. A slope angle of aa portion of the pixel definition layer 2, wherein at least a partial edge of the opening where the privacy element 32 is disposed is disposed on the portion, is greater than a slope angle of a portion of the pixel definition layer 2, wherein an edge of the opening where the normal element 31 is disposed is disposed on the portion.

The slope angle of the portion of the pixel definition layer 2, wherein the edge of the opening where the privacy element 32 is disposed is disposed on the portion, refers to an included angle between a surface of the pixel definition layer 2 in contact with the driver backplane 1 at the opening where the privacy element 32 is disposed and a sidewall of the opening. The slope angle of the portion of the pixel definition layer 2, wherein the edge of the opening where the normal element 31 is disposed is disposed on the portion, refers to an included angle between a surface of the pixel definition layer 2 in contact with the driver backplane at the opening where the normal element 31 is disposed and a sidewall of the opening. Referring to FIG. 2e, which is a schematic diagram of a range of light emitting angles of the normal element and the privacy element in some embodiment of the present disclosure, the normal element 31 refers to an element whose angular range of light emitted from its light emitting surface ranging from 120° to 160°. That is, assuming that the light emitting surface of the normal element 31, which is a flat surface, emits light at the angle of 120° the normal element 31 emits light within an angular range from 30° to 150° with respect to its light emitting surface. The privacy element 32 refers to an element whose angular range of light emitted from its light-emitting surface ranges from 40° to 50°. That is, assuming that the light-emitting surface of the privacy element 32, which is a flat surface, emits light at the angle of 30°, the privacy element 32 emits light within an angular range from 75° to 105° with respect to its light-emitting surface.

In some embodiments, both the normal element 31 and the privacy element 32 are organic light-emitting diode (OLED) devices.

In some embodiments, referring to FIG. 2a and FIG. 2b, a light-emitting device 3 is split into two (e.g., the light-emitting device 3 of the same emitting color is split into two). That is, a light-emitting device 3 is split into a normal element 31 and a privacy element 32. The privacy element 32 includes a first anode 321, a first light-emitting functional layer 322, and a first cathode 323. The first anode 321, the first light-emitting functional layer 322, and the first cathode 323 are successively stacked along a direction away from the driver backplane 1. The normal element 31 includes a second anode 311, a second light-emitting functional layer 312, and a second cathode 313. The second anode 311, the second light-emitting functional layer 312, and the second cathode 313 are successively stacked along the direction away from the driver backplane 1.

In some embodiments, the slope angle of the portion of the pixel definition layer 2, wherein the edge of the opening where the privacy element 32 is disposed is disposed on the portion, ranges from 60° to 90°.

In some embodiments, the slope angle of the portion of the edge pixel definition layer 2, wherein the opening where the normal element 31 is disposed is disposed on the portion, ranges from 20° to 30°.

In the embodiments, the slope angle of the portion of the pixel definition layer 2, wherein at least the partial edge of the opening where the privacy element 32 is disposed is disposed on the portion, is larger than the slope angle of the portion of the pixel definition layer 2, wherein the edge of the opening where the normal element 31 is disposed is disposed on the portion, such that the pixel definition layer 2 with a large slope angle shields the exiting light from at least the partial edge region on a lower side (e.g., in the case that a cross-section, perpendicular to the driver backplane 1, of the opening is in an inverted trapezoidal shape, the lower side of the opening refers to an end, close to the driver backplane 1, of the opening) of the opening where the privacy element 32 is disposed. In this way, an area of a light exiting region on the lower side of the opening of the privacy element 32 is decreased, such that a viewing angle of the privacy element 32 is restricted to a preset privacy viewing angle range, and thus ultimately the privacy display of the display panel in some privacy scenes is achieved.

In some embodiments, the pixel definition layer 2 adopts a black light-absorbing material. In some embodiments, the pixel definition layer 2 is made of a black polyimide-based material. Therefore, the pixel definition layer 2 with a large slope angle absorbs the exiting light from at least the partial edge region of the opening where the privacy element 32 is disposed, such that the exiting light from at least the partial edge region of the opening where the privacy element 32 is disposed are well shielded.

In some embodiments, referring to FIG. 2a and FIG. 2b, a surface of a side, away from the driver backplane 1, of the pixel definition layer 2 between the normal element 31 and the privacy elements 32 adjacent to each other (e.g., the normal element 31 and the privacy element 32 which are acquired by splitting the light-emitting device 3 of the same color) is a curved surface g1, and points, furthest away from the driver backplane 1, on the curved surfaces g1 are connected to form a line P1. A distance s1 between an orthographic projection of the line P1 on the driver backplane 1 and an orthographic projection on the driver backplane 1 of a first edge a of the lower side (e.g., in the case that the cross-section, perpendicular to the driver backplane 1, of the opening is in an inverted trapezoidal shape, the lower side of the opening refers to the end, close to the driver backplane 1, of the opening) of the opening where the privacy element 32 is disposed is less than a distance s2 between the orthographic projection of the line P1 on the driver backplane 1 and an orthographic projection on the driver backplane 1 a second edge b of the lower side (e.g., in the case that the cross-section, perpendicular to the driver backplane 1, of the opening is in an inverted trapezoidal shape, the lower side of the opening refers to the end, close to the driver backplane 1, of the opening) of the opening where the normal element 31 is disposed. The orthographic projections of the first edge a and the second edge b on the driver backplane 1 are disposed between the orthographic projections of the normal element 31 and the privacy element 32 on the driver backplane 1, and the orthographic projections of the first edge a and the second edge b on the driver backplane 1 are adjacent to each other.

In some embodiments, referring to FIG. 2b, a distance A between the point, furthest away from the driver backplane 1, on the curved surface g1 and the driver backplane 1 is calculated according to the following equations: tan θ=A/D.

$$tan θ1 = A / ( D - B ) .$$

$$tan θ2 = A / [ C - ( D - B ) ] .$$

$$A = tan θ * D = tan θ1 * ( D - B ) = tan θ2 * [ C - ( D - B ) ] .$$

B represents an opening width, along an arrangement direction L1 of the privacy element 32 and the normal element 31, of the lower side (e.g., in the case that the cross-section, perpendicular to the driver backplane 1, of the opening is in an inverted trapezoidal shape, the lower side of the opening refers to the end, close to the driver backplane 1, of the opening) of the opening where the privacy element 32 is disposed

C represents a maximum width of the pixel definition layer 2 disposed between the adjacent privacy element 32 and the normal element 31 along the arrangement direction L1 of the privacy element 32 and the normal element 31.

D represents the sum of, along the arrangement direction L1 of the privacy element 32 and the normal element 31, B and a distance between an orthographic projection on the driver backplane 1 of the point, farthest from the driver backplane 1, on the curved surface g1 and the orthographic projection of the first edge a on the driver backplane 1.

In some embodiments, θ=90°−α/2, wherein α represents a viewing angle of the privacy element 32.

θ1 represents the slope angle of the portion of the pixel definition layer 2, wherein the edge of the opening where the privacy element 32 is disposed is disposed on the portion.

θ2 represents the slope angle of the portion of the pixel definition layer 2, wherein the edge of the opening where the normal element 31 is disposed is disposed on the portion.

In some embodiments, assuming that θ=45°, and θ2=25°, in the case that C and B are defined to be different values, values of A and D are listed in Table 1 below.

TABLE 1
(unit in micrometers)

| C | B | A = D |
|---|---|---|
| 20 | 7.5 | 11.7 |
| 7 | 7.5 | 9 |
| 7 | 6 | 7.5 |
| 5 | 6 | 7 |

In some embodiments, referring to FIG. 2a and FIG. 2c, a surface of a side, away from the driver backplane 1, of the pixel definition layer 2 between adjacent two privacy elements 32 is a curved surface g2, and the adjacent two privacy elements 32 are a first privacy element 3201 and a second privacy element 3202. Points, furthest away from the driver backplane 1, on the curved surfaces g2 are connected to form a line P2. A distance s3 between an orthographic projection of the line P2 on the driver backplane 1 and an orthographic projection on the driver backplane 1 of a first edge d of a lower side of the opening where the first privacy element 3201 is disposed is equal to a distance s4 between the orthographic projection of the line P2 on the driver backplane 1 and an orthographic projection on the driver backplane 1 of a second edge e of a lower side of the opening where the second privacy element 3202 is disposed. The orthographic projections of the first edge d and the second edge e on the driver backplane 1 are disposed between the orthographic projections of the first privacy element 3201 and the second privacy element 3202 on the driver backplane 1, and the orthographic projections of the first edge d and the second edge e on the driver backplane 1 are adjacent to each other.

In some embodiments, a distance A1 between the point, furthest away from the driver backplane 1, on the curved surface g2 and the driver backplane 1 is calculated according to the following equations: tan θ3=A1/D1.

$$tan θ4 = A 1 / ( D 1 - B 1 ) .$$

$$tan θ5 = A 1 / [ C 1 - ( D 1 - B 1 ) ] .$$

$$A 1 = tan θ3 * D 1 = tan θ4 * ( D 1 - B 1 ) = tan θ5 * [ C 1 - ( D 1 - B 1 ) ] .$$

B1 represents an opening width, along an arrangement direction L2 of the first privacy element 3201 and the second privacy element 3202, of the lower side (e.g., in the case that the cross-section, perpendicular to the driver backplane 1, of the opening is in an inverted trapezoidal shape, the lower side of the opening refers to the end, close to the driver backplane 1, of the opening) of the opening where the first privacy element 3201 is disposed.

C1 represents a maximum width of the pixel definition layer 2 disposed between the first privacy element 3201 and the second privacy element 3202 along the arrangement direction L2 of the first privacy element 3201 and the second privacy element 3202.

D1 represents the sum, along the arrangement direction L2 of the first privacy element 3201 and the second privacy element 3202, of B1 and a distance between an orthographic projection on the driver backplane 1 of the point, furthest away from the driver backplane 1, on the curved surface g2 and the orthographic projection of the first edge d on the driver backplane 1.

In some embodiments, θ3=90°−α/2, wherein α represents a viewing angle of the first privacy element 3201.

θ4 represents a slope angle of a portion of the pixel definition layer 2, wherein the edge of the opening where the first privacy element 3201 is disposed is disposed on the portion.

θ5 represents a slope angle of a portion of the pixel definition layer 2, wherein the edge of the opening where the second privacy element 3202 is disposed is disposed on the portion.

In some embodiments, referring to FIG. 2a and FIG. 2d, a surface of a side, away from the driver backplane 1, of the pixel definition layer 2 between adjacent two normal elements 31 is a curved surface g3, and the adjacent two normal elements 31 are a first normal element 3101 and a second normal element 3102. Points, furthest away from the driver backplane 1, on the curved surfaces g3 are connected to form a line P3. A distance s5 between an orthographic projection of the line P3 on the driver backplane 1 and an orthographic projection on the driver backplane 1 of a first edge f of a lower side of the opening where the first normal element 3101 is disposed is equal to a distance s6 between the orthographic projection of the line P3 on the driver backplane 1 and an orthographic projection on the driver backplane 1 of a second edge h of a lower side of the opening where the second normal privacy element 3102 is disposed. The orthographic projections of the first edge f and the second edge h on the driver backplane 1 are disposed between the orthographic projections of the first normal element 3101 and the second normal element 3102 on the driver backplane 1, and the orthographic projections of the first edge f and the second edge h on the driver backplane 1 are adjacent to each other.

In some embodiments, referring to FIG. 2d, a distance A2 between the point, furthest away from the driver backplane 1, on the curved surface g3 and the driver backplane 1 is calculated according to the following equations: tan θ6=A2/D2.

$$tan θ7 = A 2 / ( D 2 - B 2 ) .$$

$$tan θ8 = A 2 / [ C 2 - ( D 2 - B 2 ) ] .$$

$$A 2 = tan θ6 * D 2 = tan θ7 * ( D 2 - B 2 ) = tan θ8 * [ C 2 - ( D 2 - B 2 ) ] .$$

B2 represents an opening width, along an arrangement direction L3 of the first normal element 3101 and the second normal element 3102, of the lower side (e.g., in the case that the cross-section, perpendicular to the driver backplane 1, of the opening is in an inverted trapezoidal shape, the lower side of the opening refers to the end, close to the driver backplane 1, of the opening) of the opening where the first normal element 3101 is disposed.

C2 represents a maximum width of the pixel definition layer 2 disposed between the first normal element 3101 and the second normal element 3102 along the arrangement direction L3 of the first normal element 3101 and the second normal element 3102.

D2 represents the sum, along the arrangement direction L3 of the first normal element 3101 and the second normal element 3102, of B2 and a distance between an orthographic projection on the driver backplane 1 of the point, furthest away from the driver backplane 1, on the curved surface g3 and the orthographic projection of the first edge f on the driver backplane 1.

In some embodiments, θ6=90°−α1/2, wherein α1 represents a viewing angle of the first normal element 3101.

θ7 represents a slope angle of a portion of the pixel definition layer 2, wherein the edge of the opening where the first normal element 3101 is disposed is disposed on the portion.

θ8 represents a slope angle of a portion of the pixel definition layer 2, wherein the edge of the opening where the second normal element is disposed is disposed on the portion.

In some embodiments, α ranges from 40° to 50°. Preferably, a is 45°.

In some embodiments, α1 ranges from 120° to 160°. Preferably, α1 is 120°.

In some embodiments, referring to FIG. 2a, the plurality of light-emitting devices 3 include a plurality of red light-emitting devices 301, a plurality of green light-emitting devices 302, and a plurality of blue light-emitting devices 303. The red light-emitting devices 301 include a red privacy element and a red normal element; the green light-emitting devices 302 include a green privacy element and a green normal element; and the blue light-emitting devices 303 include a blue privacy elements and blue normal elements. Portions of the pixel definition layer 2 have a same slope angle, wherein edges of openings, where the red privacy element, the green privacy element and the blue privacy element are respectively disposed, are respectively disposed on the portions, and portions of the pixel definition layer 2 have a same slope angle, wherein edges of openings, where the red privacy element, the green privacy element and the blue privacy element are respectively disposed, are respectively disposed on the portions.

In some embodiments, referring to FIG. 2a, an area of the opening where the blue privacy element is disposed >an area of the opening where the green privacy element is disposed >an area of the opening where the red privacy element is disposed. An area of the opening where the blue normal element is disposed >an area of the opening where the green normal element is disposed >an area of the opening where the red normal element is disposed.

In some embodiments, the slope angle of the portion of the pixel definition layer, wherein the edge of the opening where the green privacy element is disposed is disposed on the portion, is greater than the slope angle of the portion of the pixel definition layer, wherein the edge of the opening where the red privacy element is disposed is disposed on the portion, and the slope angle of the portion of the pixel definition layer, wherein the edge of the opening where the red privacy element is disposed is disposed on the portion, is greater than the slope angle of the portion of the pixel definition layer, wherein the edge of the opening where the blue privacy element is disposed is disposed on the portion. The human eye is sensitive to green light. Therefore, by defining the slope angles of the portions of the pixel definition layers as described above, wherein the edges of the openings where the privacy elements of different colors are respectively disposed are respectively disposed on the portions, the privacy display of the display panel achieves a better effect.

In some embodiments, referring to FIG. 2a to FIG. 2f, the line P2 and the line P3 are not in the same straight line. The distance s3 between the orthographic projection of the line P2 on the driver backplane 1 and the orthographic projection on the driver backplane 1 of the first edge d of the lower side of the opening where the first privacy element 3201 is disposed is greater than the distance s4 between the orthographic projection of the line P2 on the driver backplane 1 and the orthographic projection on the driver backplane 1 of the second edge e of the lower side of the opening where the second privacy element 3202 is disposed. The distance s5 between the orthographic projection of the line P3 on the driver backplane 1 and the orthographic projection on the driver backplane 1 of the first edge f of the lower side of the opening where the first normal element 3101 is disposed is greater than the distance s6 between the orthographic projection of the line P3 on the driver backplane 1 and the orthographic projection on the driver backplane 1 of the second edge h of the lower side of the opening where the second normal element 3102 is disposed. The distance s5 between the orthographic projection of the line P3 on the driver backplane 1 and the orthographic projection on the driver backplane 1 of the first edge f of the lower side of the opening where the first normal element 3101 is disposed is greater than the distance s3 between the orthographic projection of the line P2 on the driver backplane 1 and the orthographic projection on the driver backplane 1 of the first edge d of the lower side of the opening where the first privacy element 3201 is disposed. In this way, the slope angles are defined according to the portions of the pixel definition layers, wherein the edges of the opening where the privacy elements of different colors are respectively disposed are respectively disposed on the portions, such that the privacy display of the display panel achieves a better effect.

In some embodiments, referring to FIG. 2f, which is another sectional schematic diagram of a structure along the section line AA in FIG. 2a, the display panel further includes a first light-shielding structure 4 disposed on a side, away from the driver backplane 1, of the pixel definition layer 2. An orthographic projection of the first light-shielding structure 4 on the driver backplane 1 is disposed at an edge of the orthographic projection on the driver backplane 1 of the opening where the privacy element 32 is disposed, and the orthographic projection of the first light-shielding structure 4 on the driver backplane 1 at least covers the orthographic projection on the driver backplane 1 of the line formed by connecting the points, farthest from the driver backplane 1, on the curved surface g1 (g2).

In some embodiments, referring to FIG. 2f, a width W, along the arrangement direction L1 of the privacy element 32 and the normal element 31, and a height H, along the direction away from the driver backplane 1, of the first light-shielding structure 4 are calculated according to the following equations:

$$tan θ = ( A + H ) / D . \qquad Equation ( 1 )$$

$$tan θ2 = ( A + H ) / ( C - W - x ) . \qquad Equation ( 2 )$$

$$tan θ1 = A / x . \qquad Equation ( 3 )$$

A represents a distance between the point farthest from the driver backplane 1 on the curved surface g1 (g2) and the driver backplane 1.

D represents the sum, along the arrangement direction L1 of the privacy element 32 and the normal element 31, of B and a distance between the orthographic projection of the point, farthest from the driver backplane 1, on the curved surface g1 (g2) on the driver backplane 1 and the orthographic projection of the first edge a on the driver backplane 1.

B represents an opening width, along the arrangement direction L1 of the privacy element 32 and the normal element 31, of the lower side (e.g., in the case that the cross-section, perpendicular to the driver backplane 1, of the opening is in an inverted trapezoidal shape, the lower side of the opening refers to the end, close to the driver backplane 1, of the opening) of the opening where the privacy element 32 is disposed.

C represents a maximum width of the pixel definition layer 2 disposed between the privacy element 32 and the normal element 31 along the arrangement direction L1 of the privacy element 32 and the normal element 31.
x represents a shortest distance between the orthographic projection of the first light-shielding structure 4 on the driver backplane 1 and the orthographic projection of the first edge a on the driver backplane 1.

θ=90°−α/2, wherein α represents a viewing angle of the privacy element 32.

θ1 represents a slope angle of a portion of the pixel definition layer 2, wherein the edge of the opening where the privacy element 32 is disposed is disposed on the portion.

θ2 represents a slope angle of a portion of the pixel definition layer 2, wherein the edge of the opening where the normal element 31 is disposed is disposed on the portion.

The height H of the first light-shielding structure 4 is calculated according to equation (1). From equation (2) and equation (3), it is derived that tan θ2=(A+H)/[C−W−(A/tan θ1)]. Then, it is derived that [C−W−(A/tan θ1)] tan θ2=D*tan θ. In the case where A, C, D, θ, θ1, and θ2 are determined, the width W of the first light-shielding structure 4 is acquired by calculation.

In the present embodiments, by providing the first light-shielding structure 4, on the basis that the exiting light from the edge region of the opening where the privacy element 32 is disposed is shielded by the pixel definition layer 2 with a large slope angle, the exiting light from the edge region of the opening where the privacy element 32 is disposed exited through the pixel definition layer 2 with a large slope angle is further shielded. In this way, the area of the light exiting region of the opening where the privacy element 32 is disposed is further decreased, and thus the viewing angle of the privacy element 32 is well restricted to a preset privacy viewing angle range.

FIG. 2g is another sectional schematic diagram of a structure along the section line AA in FIG. 2a. FIG. 2h is still another sectional schematic diagram of a structure along the section line AA in FIG. 2a. FIG. 2i is yet still another sectional schematic diagram of a structure along the section line AA in FIG. 2a. In some embodiments, referring to FIG. 2g, FIG. 2h, and FIG. 2i, on the basis of the structure of the display panel illustrated in FIG. 2f, the display panel further includes a package layer 5 and a second light-shielding structure 6. The package layer 5 is disposed on a side, away from the driver backplane 1, of the first light-shielding structure 4, and is configured to package the light-emitting device 3. The package layer 5 includes more than three sub-layers, which are successively stacked along the direction away from the driver backplane 1. The second light-shielding structure 6 is disposed between at least some of the adjacent sub-layers. An orthographic projection of the second light-shielding structure 6 on the driver backplane 1 is disposed at an edge of the orthographic projection on the driver backplane 1 of the opening where the privacy element 32 is disposed, and the orthographic projection of the second light-shielding structure 6 on the driver backplane 1 is at least partially overlapped with the orthographic projection of the first light-shielding structure 4 on the driver backplane 1.

In some embodiments, referring to FIG. 2g, the package layer 5 includes three sub-layers, i.e., a first inorganic layer 51, an organic layer 52, and a second inorganic layer 53 that are successively stacked. The second light-light-shielding structure 6 is disposed between the first inorganic layer 51 and the organic layer 52.

In some embodiments, a height of the second light-shielding structure 6 is less than a thickness of the organic layer 52, a width, along the arrangement direction L1 of the privacy element 32 and the normal element 3, of the second light-shielding structure 6 is equal to a width of the first light-shielding structure 4, and the orthographic projection of the second light-shielding structure 6 on the driver backplane 1 is closer to the orthographic projection on the driver backplane 1 of the opening where the privacy element 32 is disposed relative to the orthographic projection of the first light-shielding structure 4 on the driver backplane 1.

In some embodiments, referring to FIG. 2h, the package layer 5 includes four sub-layers, i.e., a first inorganic layer 51, a first organic layer 521, a second organic layer 522, and a second inorganic layer 53 that are successively stacked, and the second light-shielding structure 6 is disposed between the first inorganic layer 51 and the first organic layer 521 and between the first organic layer 521 and the second organic layer 522.

In some embodiments, referring to FIG. 2j, which is a top-view schematic diagram of an arrangement of a first light-shielding structure and a second light-shielding structure according to some embodiments of the present disclosure, a width, along the arrangement direction L1 of the privacy element 32 and the normal element 31, of the second light-shielding structure 6 is equal to a width of the first light-shielding structure 4. A height of the second light-shielding structure 6 disposed between the first inorganic layer 51 and the first organic layer 521 is less than a thickness of the first organic layer 521. A height of the second light-shielding structure 6 disposed between the first organic layer 521 and the second organic layer 522 is less than a thickness of the second organic layer 522. Orthographic projections of the second light-shielding structure 6 disposed between the first organic layer 521 and the second organic layer 522, the second light-shielding structure 6 disposed between the first inorganic layer 51 and the first organic layer 521, and the first light-shielding structure 4 on the driver backplane 1 are successively away from the orthographic projection on the driver backplane 1 of the opening where the privacy element 32 is disposed.

In some embodiments, referring to FIG. 2i, the package layer 5 includes four sub-layers, i.e., a first inorganic layer 51, an organic layer 52, a second inorganic layer 53, and a third inorganic layer 54 that are successively stacked, and the second light-shielding structure 6 is disposed between the first inorganic layer 51 and the organic layer 52 and between the second inorganic layer 53 and the third inorganic layer 54.

In some embodiments, a width, along the arrangement direction L1 of the privacy element 32 and the normal element 31, of the second light-shielding structure 6 is equal to a width of the first light-shielding structure 4. A height of the second light-shielding structure 6 disposed between the first inorganic layer 51 and the organic layer 52 is less than a thickness of the organic layer 52. A height of the second light-shielding structure 6 disposed between the second inorganic layer 53 and the third inorganic layer 54 is less than a thickness of the third organic layer 54. Orthographic projections of the second light-shielding structure 6 disposed between the second inorganic layer 53 and the third inorganic layer 54, the second light-shielding structure 6 disposed between the first inorganic layer 51 and the organic layer 52, and the first light-shielding structure 4 on the driver backplane 1 are successively away from the orthographic projection on the driver backplane 1 of the opening where the privacy element 32 is disposed.

In the present embodiments, by providing the second light-shielding structure 6, on the basis that the exiting light from the edge region of the opening where the privacy element 32 is disposed is shielded by the first light-shielding structure 4 and the pixel definition layer 2 with a large slope angle, the exiting light from the edge region of the opening where the privacy element 32 is disposed exited through the pixel definition layer 2 with a large slope angle is further shielded. In this way, the area of the light exiting region of the opening where the privacy element 32 is disposed is further decreased, and thus the viewing angle of the privacy element 32 is well restricted to a preset privacy viewing angle range.

In some embodiments, the first light-shielding structure 4 and the second light-shielding structure 6 are made of a black organic material, such as a black acrylic-based material, a black resin material, and the like.

In some embodiments, an optical density (OD) value of the black material of the first light-shielding structure 4 and the second light-shielding structure 6 is greater than that of the black material of the pixel definition layer 2.

In the display panel according to the embodiments of the present disclosure, by defining the slope angle of the portion of the pixel definition layer, wherein at least the partial edge of the opening where the privacy element is disposed is disposed on the portion, to be greater than the slope angle of the portion of the pixel definition layer, wherein the edge of the opening where the normal element is disposed is disposed on the portion, the exiting light from at least the partial edge region of the opening where the privacy element is disposed is shielded by the pixel definition layer with a large slope angle. In this way, the area of the light exiting region of the opening where the privacy element is disposed is decreased, such that the viewing angle of the privacy element is restricted to a preset privacy viewing angle range, and thus the privacy display of the display panel in some privacy scenarios is ultimately achieved.

Based on the above structure of the display panel, some embodiments of the present disclosure further provide a method for driving the display panel. In the case that the display panel is displayed in a normal state, the driver backplane drives the normal element and the privacy element in the light-emitting device to emit light. In the case that the display panel is displayed in a privacy state, the driver backplane drives the privacy element in the light-emitting device to emit light.

Specifically, in the case that the display panel is displayed in the normal state (e.g., the normal state indicates that the display panel is displayed within a viewing angle of) 120°, a pixel circuit in the driver backplane drives the normal element and the privacy element in the light-emitting device to emit light, such that the normal display of the display panel is achieved. In the case that the display panel is displayed in the privacy state (e.g., the privacy state indicates that the display panel is displayed within a viewing angle of) 45°, the pixel circuit in the driver backplane drives only the privacy element in the light-emitting device to emit light, such that the privacy display of the display panel is achieved

Based on the above structure of the display panel, some embodiments of the present disclosure further provide a method for preparing the display pane, the method includes the following steps. In step S01, a driver backplane is prepared.

In step S02, anodes of a plurality of light-emitting devices are prepared on a side of the driver backplane. The preparation of the anodes of the light-emitting devices includes preparing anodes of normal elements and anodes of privacy elements by a one-time patterning process.

In step S03, a pixel definition layer and a plurality of openings of the pixel definition layer are prepared on a side, away from the driver backplane, of the anode. A slope angle of a portion of the pixel definition layer, wherein at least a partial edge of the opening where the privacy element is disposed is disposed on the portion, is greater than a slope angle of a portion of the pixel definition layer, wherein an edge of the opening where the normal element is disposed is disposed on the portion.

In step S04, a light-emitting functional layer and a cathode of the light-emitting device are successively prepared. The light-emitting functional layers and the cathodes of the privacy element and the normal element are prepared in different openings.

In some embodiments, preparing the pixel definition layer and the plurality of openings in the pixel definition layer in step S03 includes the following sub-steps. In step S031, a pixel definition layer film is formed on the side, away from the driver backplane, of the anode by coating.

In step S032, the slope angle ∠2 of the portion of the pixel definition layer, wherein the edge of the opening where the privacy element is disposed is disposed on the portion, is formed by an exposure and development process, and a step is formed simultaneously on a side, away from the driver backplane, of a pixel definition layer film 7 at the edge of the opening where the normal element is disposed.

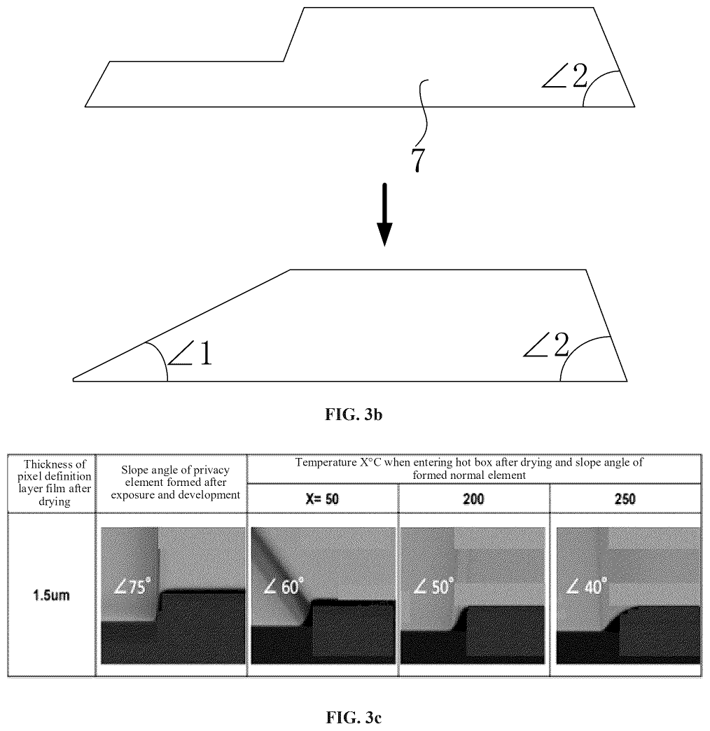

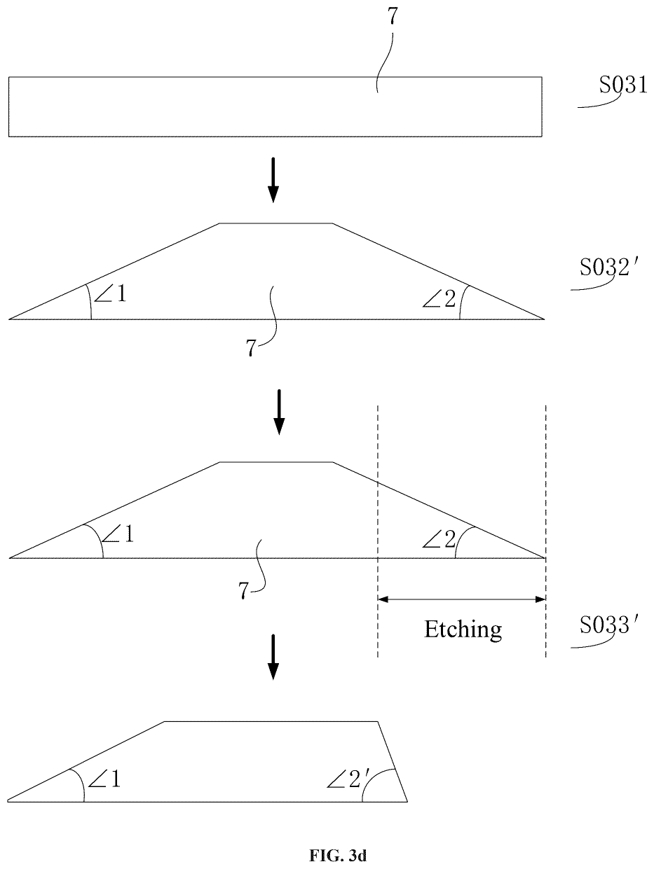

In this step, referring to FIG. 3a, which is a schematic diagram of step S032 in a method for preparing a display panel according to some embodiments of the present disclosure, the pixel definition layer film 7 is directly exposed. Specifically, by setting different slit diffraction, the pixel definition layer film 7 at the edge of the opening where the privacy element is disposed is exposed by 100%, and the pixel definition layer film 7 at the edge of the opening where the normal element is disposed is exposed by 50%, such that the exposure energy to the pixel definition layer film 7 at the edge of the opening where the normal element is disposed is reduced, and thus the step is formed on the side on the side, away from the driver backplane, of the pixel definition layer film 7 at the edge of the opening where the normal element is disposed after the exposure and development process.

In step S033: the pixel definition layer film 7 is dried, and the display panel maintained at the drying temperature is put into a hot box, and removed after being held in the hot box for a defined length of time, such that a slope angle ∠1 of the portion of the pixel definition layer, wherein the edge of the opening where the normal element is disposed is disposed on the portion, is formed.

In this step, referring to FIG. 3b, which is a schematic diagram of step S033 in a method for preparing a display panel according to some embodiments of the present disclosure, by the hot-in-cold-out hot box, the small slope angle ∠1 of the portion of the pixel definition layer, wherein the edge of the opening where the normal element is disposed is disposed on the portion, is formed using the self-leveling property of the pixel definition layer material. FIG. 3c is a comparative diagram of parameters and effects of slope angles of pixel definition layers formed by a hot-in-cold-out hot box in a method for preparing a display panel according to some embodiments of the present disclosure. Referring to FIG. 3c, the display panel at 250° C. is put into a hot box at a temperature of 250° C. and is removed after being kept for 60 minutes, and a slope angle of 40° is formed.

In some embodiments, referring to FIG. 3d, which is a schematic diagram of another method for preparing a display panel according to some embodiments of the present disclosure, preparing the pixel definition layer and the plurality of openings in the pixel definition layer in step S03 includes the following sub-steps. In step S031: a pixel definition layer film 7 is formed on a side, away from the driver backplane, of the anode by coating.

In step S032′, an initial slope angle ∠2 of the portion of the pixel definition layer film 7, wherein the edge of the opening where the privacy element is disposed is disposed on the portion, and a slope angle ∠1 of the portion of the pixel definition layer, wherein the edge of the opening where the normal element is disposed is disposed on the portion, are formed by an exposure and development process. The initial slope angle ∠2 of the portion of the pixel definition layer film, wherein the edge of the opening where the privacy element is disposed is disposed on the portion, is equal to the slope angle ∠1 of the portion of the pixel definition layer, wherein the edge of the opening where the normal element is disposed is disposed on the portion.

In step S033′, a slope angle ∠2′ of the portion of the pixel definition layer, wherein the edge of the opening where the privacy element is disposed is disposed on the portion, is formed by etching the initial slope angle ∠2 by an etching process.

In this step, a pattern of an organic mask layer or an inorganic mask layer is formed on a side, away from the driver backplane, of the pixel definition layer film. The initial slope angle of the portion of the pixel definition layer film, wherein the edge of the opening where the privacy element is disposed is disposed on the portion, on the pattern of the organic mask layer or the inorganic mask layer is exposed, and the slope angle of the portion of the pixel definition layer, wherein the edge of the opening where the privacy element is disposed is disposed on the portion, is formed by etching the initial slope angle using a dry etching process.

In some embodiments, during the etching, relative to employing the organic mask layer, by employing the inorganic mask layer, the pixel definition layer film made of the inorganic mask layer and organic material has a higher etching selection ratio, which is conducive to achieving a large slope angle in the pixel definition layer film. The experimental validation has found that a slope angle of a portion of the pixel definition layer film acquired by using an inorganic mask layer is up to 90°.

In this step S033′, during the dry etching process, the dry etching is directly performed on the initial slope angle by using a laser, such that the slope angle of the portion of the pixel definition layer, wherein the edge of the opening where the privacy element is disposed is disposed on the portion, is formed. In some embodiments, a display substrate on which the pixel definition layer film is formed is placed with the pixel definition layer film facing downward, and the laser etching equipment is located below the display substrate. Then, the laser etching is performed at a position where the initial slope angle is disposed by means of forming holes in the inorganic mask layer. In this way, a slope angle of 90° of the portion of the pixel definition layer, wherein the edge of the opening where the privacy element is disposed is disposed on the portion, is realized.

Some embodiments of the present disclosure further provide a display device. The display device includes the display panel as described above.

By employing the display panel as described above, in one aspect, a normal display (i.e., the display of a large viewing angle range, such as a large viewing angle range from 120° to) 160° is achieved; in another aspect, a privacy display (i.e., the display of a privacy viewing angle range, such as a privacy viewing angle range from 40° to) 50° of the display device is achieved.

The display device according to the embodiments of the present disclosure may be an OLED panel, an OLED TV, an OLED billboard, a monitor, a smartphone, a navigator, and any other product or component having a display function.

Described above are merely exemplary embodiments of the present disclosure, and are not intended to limit the present disclosure. Therefore, for those skilled in the art, any modifications, equivalent substitutions, improvements, and the like made within the spirit and principles of the present disclosure shall be included in the protection scope of the present disclosure.

1. A display panel, comprising: a driver backplane, a pixel definition layer, and a plurality of light-emitting devices; wherein
the pixel definition layer is disposed on a side of the driver backplane, and a plurality of openings are formed in the pixel definition layer;
each of the light-emitting devices comprises a normal element and at least one privacy element, wherein the privacy element and the normal element are respectively disposed in different openings of the plurality of openings; and
a slope angle of a portion of the pixel definition layer, wherein at least a partial edge of the opening where the privacy element is disposed is disposed on the portion, is greater than a slope angle of a portion of the pixel definition layer, wherein an edge of the opening where the normal element is disposed is disposed on the portion.

2. The display panel according to claim 1, wherein
the slope angle of the portion of the pixel definition layer, wherein the edge of the opening where the privacy element is disposed is disposed on the portion, ranges from 60° to 90°; and
the slope angle of the portion of the pixel definition layer, wherein the edge of the opening where the normal element is disposed is disposed on the portion, ranges from 20° to 30°.

3. The display panel according to claim 1, wherein the pixel definition layer is made of a black light-absorbing material.

4. The display panel according to claim 1, wherein
a surface on a side, away from the driver backplane, of the pixel definition layer disposed between the normal element and the privacy element that are adjacent to each other is a curved surface;
points, farthest from the driver backplane, on the curved surfaces are connected to form a line, wherein a distance between an orthographic projection of the line on the driver backplane and an orthographic projection on the driver backplane of a first edge of the opening where the privacy element is disposed is less than a distance between the orthographic projection of the line on the driver backplane and an orthographic projection on the driver backplane of a second edge of the opening where the normal element is disposed; and
the orthographic projections of the first edge and the second edge on the driver backplane are disposed between orthographic projections of the normal element and the privacy element on the driver backplane, and the orthographic projections of the first edge and the second edge on the driver backplane are adjacent to each other.

5. The display panel according to claim 4, wherein equations for calculating a distance A between the point, furthest from the driver backplane, on the curved surface and the driver backplane are as follows:
$$tan θ = A / D ;$$
$$tan θ1 = A / ( D - B ) ;$$
$$tan θ2 = A / [ C - ( D - B ) ] ; and$$
$$A = tan θ * D = tan θ1 * ( D - B ) = tan θ2 * [ C - ( D - B ) ] ;$$
wherein
B represents an opening width, along an arrangement direction of the privacy element and the normal element, of the opening where the privacy element is disposed;
C represents a maximum width, along the arrangement direction of the privacy element and the normal element, of the pixel definition layer disposed between the privacy element and the normal element that are adjacent to each other;
D represents a sum, along the arrangement direction of the privacy element and the normal element, of B and a distance between an orthographic projection on the driver backplane of the point, farthest from the driver backplane, on the curved surface and the orthographic projection of the first edge on the driver backplane; and
θ=90°−α/2, wherein α represents a viewing angle of the privacy element, θ1 represents the slope angle of the portion of the pixel definition layer, wherein the edge of the opening where the privacy element is disposed is disposed on the portion, and θ2 represents the slope angle of the portion of the pixel definition layer, wherein the edge of the opening where the normal element is disposed is disposed on the portion.

6. The display panel according to claim 1, wherein
a surface on a side, away from the driver backplane, of the pixel definition layer disposed between adjacent two of the privacy elements is a curved surface, wherein the adjacent two privacy elements are respectively a first privacy element and a second privacy element;
points, farthest from the driver backplane, on the curved surfaces are connected to form a line, wherein a distance between an orthographic projection of the line on the driver backplane and an orthographic projection on the driver backplane of a first edge of an opening where the first privacy element is disposed is equal to a distance between the orthographic projection of the line on the driver backplane and an orthographic projection on the driver backplane of a second edge of an opening where the second privacy element is disposed; and
the orthographic projections of the first edge and the second edge on the driver backplane are disposed between orthographic projections of the first privacy element and the second privacy element on the driver backplane, and the orthographic projections of the first edge and the second edge on the driver backplane are adjacent to each other.

7. The display panel according to claim 6, wherein equations for calculating a distance A1 between the point, farthest from the driver backplane, on the curved surface and the driver backplane are as follows:
$$tan θ3 = A 1 / D 1 ;$$
$$tan θ4 = A 1 / ( D 1 - B 1 ) ;$$
$$tan θ5 = A 1 / [ C 1 - ( D 1 - B 1 ) ] ; and$$
$$A 1 = tan θ3 * D 1 = tan θ4 * ( D 1 - B 1 ) = tan θ5 * [ C 1 - ( D 1 - B 1 ) ] ;$$
wherein
B1 represents an opening width, along an arrangement direction of the first privacy element and the second privacy element, of the opening where the first privacy element is disposed;
C1 represents a maximum width, along the arrangement direction of the first privacy element and the second privacy element, of the pixel definition layer disposed between the first privacy element and the second privacy element;
D1 represents a sum, along the arrangement direction of the first privacy element and the second privacy element, of B1 and a distance between an orthographic projection on the driver backplane of the point, farthest from the driver backplane, on the curved surface and the orthographic projection of the first edge on the driver backplane; and
θ3=90°−α/2, wherein α represents a viewing angle of the first privacy element, θ4 represents a slope angle of a portion of the pixel definition layer, wherein an edge of the opening where the first privacy element is disposed is disposed on the portion, and θ5 represents a slope angle of a portion of the pixel definition layer, wherein an edge of the opening where the second privacy element is disposed is disposed on the portion.

8. The display panel according to claim 1, wherein
a surface on a side, away from the driver backplane, of the pixel definition layer disposed between adjacent two of the normal elements is a curved surface, wherein the adjacent two normal elements are respectively a first normal element and a second normal element;
points, farthest from the driver backplane, on the curved surfaces are connected to form a line, wherein a distance between an orthographic projection of the line on the driver backplane and an orthographic projection on the driver backplane of a first edge of an opening where the first normal element is disposed is equal to a distance between the orthographic projection of the line on the driver backplane and an orthographic projection on the driver backplane of a second edge of an opening where the second normal element is disposed; and
the orthographic projections of the first edge and the second edge on the driver backplane are disposed between orthographic projections of the first normal element and the second normal element on the driver backplane, and the orthographic projections of the first edge and the second edge on the driver backplane are adjacent to each other.

9. The display panel according to claim 8, wherein equations for calculating a distance A2 between the point, farthest from the driver backplane, on the curved surface and the driver backplane are as follows:
$$tan θ6 = A 2 / D 2 ;$$
$$tan θ7 = A 2 / ( D 2 - B 2 ) ;$$
$$tan θ8 = A 2 / [ C 2 - ( D 2 - B 2 ) ] ; and$$
$$A 2 = tan θ6 * D 2 = tan θ7 * ( D 2 - B 2 ) = tan θ8 * [ C 2 - ( D 2 - B 2 ) ] ;$$
wherein
B2 represents an opening width, along an arrangement direction of the first normal element and the second normal element, of the opening where the first normal element is disposed;
C2 represents a maximum width, along the arrangement direction of the first normal element and the second normal element, of the pixel definition layer disposed between the first normal element and the second normal element;
D2 represents a sum, along the arrangement direction of the first normal element and the second normal element, of B2 and a distance between an orthographic projection on the driver backplane of the point, farthest from the driver backplane, on the curved surface and the orthographic projection of the first edge on the driver backplane; and
θ6=90°−α1/2, wherein α1 represents a viewing angle of the first normal element, θ7 represents a slope angle of a portion of the pixel definition layer, wherein an edge of the opening where the first normal element is disposed is disposed on the portion, and θ8 represents a slope angle of a portion of the pixel definition layer, wherein an edge of the opening where the second normal element is disposed is disposed on the portion.

10. The display panel according to claim 5, wherein α ranges from 40° to 50°.

11. The display panel according to claim 9, wherein α1 ranges from 120° to 160°.

12. The display panel according to claim 1, wherein the plurality of light-emitting devices comprise a plurality of red light-emitting devices, a plurality of green light-emitting devices, and a plurality of blue light-emitting devices; wherein
the red light-emitting devices comprise a red privacy element and a red normal element;
the green light-emitting devices comprise a green privacy element and a green normal element;
the blue light-emitting devices comprise a blue privacy element and a blue normal element;
portions of the pixel definition layer have a same slope angle, wherein edges of openings, where the red privacy element, the green privacy element and the blue privacy element are respectively disposed, are respectively disposed on the portions; and
portions of the pixel definition layer have a same slope angle, wherein edges of openings, where the red normal element, the green normal element and the blue normal element are respectively disposed, are respectively disposed on the portions.

13. The display panel according to claim 4, further comprising: a first light-shielding structure disposed on the side, away from the driver backplane, of the pixel definition layer;
wherein an orthographic projection of the first light-shielding structure on the driver backplane is disposed at an edge of an orthographic projection on the driver backplane of an opening where the privacy element is disposed, and the orthographic projection of the first light-shielding structure on the driver backplane at least covers the orthographic projection on the driver backplane of the line formed by connecting the points, farthest from the driver backplane, on the curved surfaces.

14. The display panel according to claim 13, further comprising: a package layer and a second light-shielding structure; wherein
the package layer is disposed on a side, away from the driver backplane, of the first light-shielding structure and is configured to package the light-emitting device;
the package layer comprises more than three sub-layers, wherein the more than three sub-layers are successively stacked along a direction away from the driver backplane;
the second light-shielding structure is disposed between at least some of the adjacent sub-layers; and
an orthographic projection of the second light-shielding structure on the driver backplane is disposed at the edge of the orthographic projection on the driver backplane of the opening where the privacy element is disposed, and the orthographic projection of the second light-shielding structure on the driver backplane is at least partially overlapped with the orthographic projection of the first light-shielding structure on the driver backplane.

15. The display panel according to claim 13, wherein equations for calculating a width W, along an arrangement direction of the privacy element and the normal element, of the first light-shielding structure and a height H, along a direction away from the driver backplane, of the first light-shielding structure are as follows:
$$tan θ = ( A + H ) / D ;$$
$$tan θ2 = ( A + H ) / ( C - W - x ) ; and$$
$$tan θ1 = A / x ;$$
wherein
A represents a distance between the point, farthest from the driver backplane, on the curved surface and the driver backplane;
D represents a sum, along the arrangement direction of the privacy element and the normal element, of B and a distance between an orthographic projection on the driver backplane of the point, farthest from the driver backplane, on the curved surface and the orthographic projection of the first edge on the driver backplane;
B represents an opening width, along the arrangement direction of the privacy element and the normal element, of the opening where the privacy element is disposed;
C represents a maximum width, along the arrangement direction of the privacy element and the normal element, of the pixel definition layer disposed between the privacy element and the normal element that are adjacent to each other;
x represents a shortest distance between the orthographic projection of the first light-shielding structure on the driver backplane and the orthographic projection of the first edge on the driver backplane; and
θ=90°−α/2, wherein α represents a viewing angle of the privacy element, θ1 represents a slope angle of a portion of the pixel definition layer, wherein an edge of the opening where the privacy element is disposed is disposed on the portion, and θ2 represents a slope angle of a portion of the pixel definition layer, wherein an edge of the opening where the normal element is disposed is disposed on the portion.

16. The display panel according to claim 14, wherein the first light-shielding structure and the second light-shielding structure are made of a black organic material.

17. A method for preparing a display panel, comprising:
preparing a driver backplane;
preparing anodes of a plurality of light-emitting devices on a side of the driver backplane, wherein preparing the anodes of the plurality of light-emitting devices comprises preparing anodes of normal elements and anodes of privacy elements by a one-time patterning process; and
preparing a pixel definition layer and a plurality of openings in the pixel definition layer on a side, away from the driver backplane, of the anode;
wherein a slope angle of a portion of the pixel definition layer, wherein at least a partial edge of an opening where the privacy element is disposed is disposed on the portion, is greater than a slope angle of a portion of the pixel definition layer, wherein an edge of an opening where the normal element is disposed is disposed on the portion.

18. A display device, comprising: a display panel; wherein
the display panel comprises: a driver backplane, a pixel definition layer, and a plurality of light-emitting devices; wherein
the pixel definition layer is disposed on a side of the driver backplane, and a plurality of openings are formed in the pixel definition layer;
each of the light-emitting devices comprises a normal element and at least one privacy element, wherein the privacy element and the normal element are respectively disposed in different openings of the plurality of openings; and
a slope angle of a portion of the pixel definition layer, wherein at least a partial edge of the opening where the privacy element is disposed is disposed on the portion, is greater than a slope angle of a portion of the pixel definition layer, wherein an edge of the opening where the normal element is disposed is disposed on the portion.

19. The display device according to claim 18, wherein
the slope angle of the portion of the pixel definition layer, wherein the edge of the opening where the privacy element is disposed is disposed on the portion, ranges from 60° to 90°; and
the slope angle of the portion of the pixel definition layer, wherein the edge of the opening where the normal element is disposed is disposed on the portion, ranges from 20° to 30°.

20. The display device according to claim 18, wherein the pixel definition layer is made of a black light-absorbing material.
